(19) United States
(12) Patent Application Publication
(10) Pub. No.: US 2010/0208512 A1
(43) Pub. Date: Aug. 19, 2010

(54) SEMICONDUCTOR MEMORY DEVICE PROVIDED WITH RESISTANCE CHANGE ELEMENT

(75) Inventor: Yoshihiro UEDA, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/709,256

(22) Filed: Feb. 19, 2010

(30) Foreign Application Priority Data
Feb. 19, 2009 (JP) 2009-036701

(51) Int. Cl. G11C 11/00

(52) U.S. Cl. 365/148; 365/158; 365/163

(57) ABSTRACT

A latch circuit is connected to a first common node, a first, second output node, and a first, second connection node. A first resistance change element is connected to the first connection node, and a second common node. A second resistance change element is connected to the second connection node, and the second common node. When a first data is stored, voltages of the first common node, second common node, and first output node are set at a first reference voltage, and a voltage of the second output node is set at a second reference voltage. When a second data is stored, voltages of the first common node, second common node, and second output node are set at the first reference voltage, and a voltage of the first output node is set at the second reference voltage.

### CROSS-REFERENCE TO RELATED APPLICATIONS

This application is based upon and claims the benefit of priority from prior Japanese Patent Application No. 2009-036701, filed Feb. 19, 2009, the entire contents of which are incorporated herein by reference.

### BACKGROUND OF THE INVENTION

1. Field of the Invention

The present invention relates to a semiconductor memory device provided with a resistance change element configured in such a manner that data is written thereto by directly applying a current thereto.

2. Description of the Related Art

As memories using a resistance change element, a magnetoresistive random access memory (MRAM), resistance random access memory (ReRAM), phase-change random access memory (PRAM), and the like are known. It is desirable that ROM data used in the peripheral circuit of these memories be stored in a memory (ROM) using the same type of resistance change element. In this ROM, when the memory is to be initiated, a read operation is carried out in advance. As a result of this, the ROM is brought into a state where the ROM can output ROM data.

In U.S. Pat. No. 6,515,895, a technique that realizes a ROM using an MRAM element of the induced magnetic field write type is disclosed. However, the method of U.S. Pat. No. 6,515,895 cannot be applied to an element such as an MRAM element, ReRAM element, PRAM element or the like of the spin injection type configured in such a manner that data is written thereto by directly applying a current thereto.

### BRIEF SUMMARY OF THE INVENTION

According to a first aspect of the invention, there is provided a semiconductor memory device comprising a memory circuit, wherein the memory circuit comprises: a first transistor of a first conductivity type, a drain of which is connected to a first output node, a gate of which is connected to a second output node, and a source of which is connected to a first common node; a second transistor of the first conductivity type, a drain of which is connected to the second output node, a gate of which is connected to the first output node, and a source of which is connected to the first common node; a third transistor of a second conductivity type, a drain of which is connected to the first output node, a gate of which is connected to the second output node, and a source of which is connected to a first connection node; a fourth transistor of the second conductivity type, a drain of which is connected to the second output node, a gate of which is connected to the first output node, and a source of which is connected to a second connection node; a first resistance change element, one end of which is connected to the first connection node, and the other end of which is connected to a second common node; and a second resistance change element, one end of which is connected to the second connection node, and the other end of which is connected to the second common node, when the memory circuit stores therein first data, voltages of the first common node, the second common node, and the first output node are set at a first reference voltage, and a voltage of the second output node is set at a second reference voltage different from the first reference voltage, whereby a current is directly applied to the second resistance change element, and when the memory circuit stores therein second data, voltages of the first common node, the second common node, and the second output node are set at the first reference voltage, and a voltage of the first output node is set at the second reference voltage, whereby a current is directly applied to the first resistance change element. According to a second aspect of the invention, there is provided a semiconductor memory device comprising a memory circuit, wherein the memory circuit comprises: a latch circuit connected to a first common node, a first output node, a second output node, a first connection node, and a second connection node; a first resistance change element one end of which is connected to the first connection node, and the other end of which is connected to a second common node; and a second resistance change element one end of which is connected to the second connection node, and the other end of which is connected to the second common node, when the memory circuit stores therein first data, voltages of the first common node, the second common node, and the first output node are set at a first reference voltage, and a voltage of the second output node is set at a second reference voltage different from the first reference voltage, whereby a current is directly applied to the second resistance change element, and when the memory circuit stores therein second data, voltages of the first common node, the second common node, and the second output node are set at the first reference voltage, and a voltage of the first output node is set at the second reference voltage, whereby a current is directly applied to the first resistance change element.

### BRIEF DESCRIPTION OF THE SEVERAL VIEWS OF THE DRAWING

FIG. 1 is a circuit configuration diagram showing a ROM cell according to a first embodiment of the present invention.

FIG. 2 is a circuit configuration diagram showing a ROM cell array according to the first embodiment of the present invention.

FIG. 3 is a block diagram showing the ROM cell according to the first embodiment of the present invention.

FIGS. 4A, 4B and 4C are schematic views each showing a write operation according to the first embodiment of the present invention.

FIG. 5 is a timing chart showing a binary 1 write (“1” write) operation and read operation according to the first embodiment of the present invention.

FIG. 6 is a timing chart showing a binary 0 write (“0” write) operation and read operation according to the first embodiment of the present invention.

FIGS. 7A and 7B are schematic views each showing an initialization operation of the first embodiment of the present invention.

FIG. 8 is a timing chart showing a binary 1 write operation and read operation according to a second embodiment of the present invention.

FIG. 9 is a timing chart showing a binary 0 write operation and read operation according to the second embodiment of the present invention.

FIG. 10 is a schematic view showing an initialization operation of a third embodiment of the present invention.

### DETAILED DESCRIPTION OF THE INVENTION

Embodiments of the present invention will be described below with reference to the drawings. In the drawings, the same parts are denoted by the same reference symbols.

### First Embodiment

### [1-1] Circuit Configuration of Cell

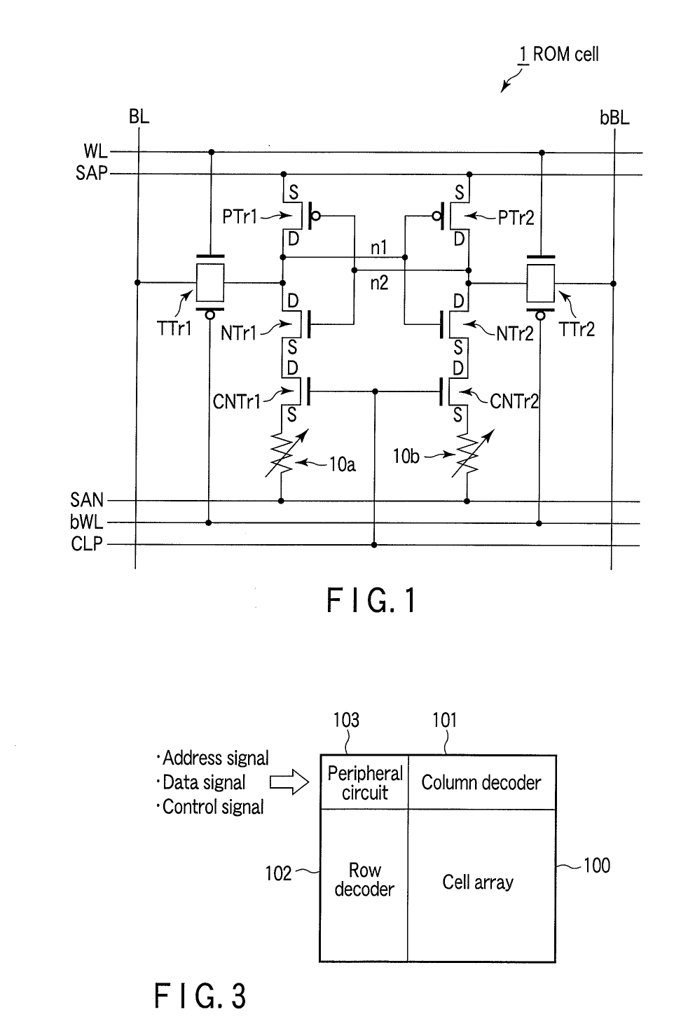

The circuit configuration of a ROM cell according to a first embodiment of the present invention will be described with reference to FIG. 1.

As shown in FIG. 1, a ROM cell 1 comprises PMOS transistors PTr1 and PTr2, NMOS transistors NTr1 and NTr2, voltage clamp NMOS transistors CNTr1 and CNTr2, resistance change elements 10a and 10b, and CMOS transfer gate transistors TTr1 and TTr2.

PMOS transistors PTr1 and PTr2 make a pair, and are cross-coupled. NMOS transistors NTr1 and NTr2 make a pair, and are cross-coupled. These cross-coupled PMOS transistors PTr1 and PTr2, and NMOS transistors NTr1 and NTr2 constitute a latch circuit.

More specifically, in PMOS transistor PTr1, a drain is connected to a first output node n1, a gate is connected to a second output node n2, and a source is connected to a first common node SAP. In PMOS transistor PTr2, a drain is connected to the second output node n2, a gate is connected to the first output node n1, and a source is connected to the first common node SAP. In NMOS transistor NTr1, a drain is connected to the first output node n1, and a gate is connected to the second output node n2. In NMOS transistor NTr2, a drain is connected to the second output node n2, and a gate is connected to the first output node n1.

One of a pair of voltage clamp NMOS transistors CNTr1 and CNTr2 is connected to the source of each of the cross-coupled NMOS transistors NTr1 and NTr2. Here, a drain of voltage clamp NMOS transistor CNTr1 is connected to the source of NMOS transistor NTr1. Further, a drain of voltage clamp NMOS transistor CNTr2 is connected to the source of NMOS transistor NTr2. A clamp control voltage CLP is applied to a gate of each of voltage clamp NMOS transistors CNTr1 and CNTr2.

An end of each of resistance change elements 10a and 10b is connected to a source of each of voltage clamp NMOS transistors CNTr1 and CNTr2. A second common node SAN is connected to the other end of each of the resistance change elements.

Bit lines BL and bBL are connected to the complementary first and second output nodes n1 and n2 of the latch circuit through CMOS transfer gate transistors TTr1 and TTr2. CMOS transfer gate transistors TTr1 and TTr2 are controlled by word lines WL and bWL.

### [1-2] Circuit Configuration of Cell Array

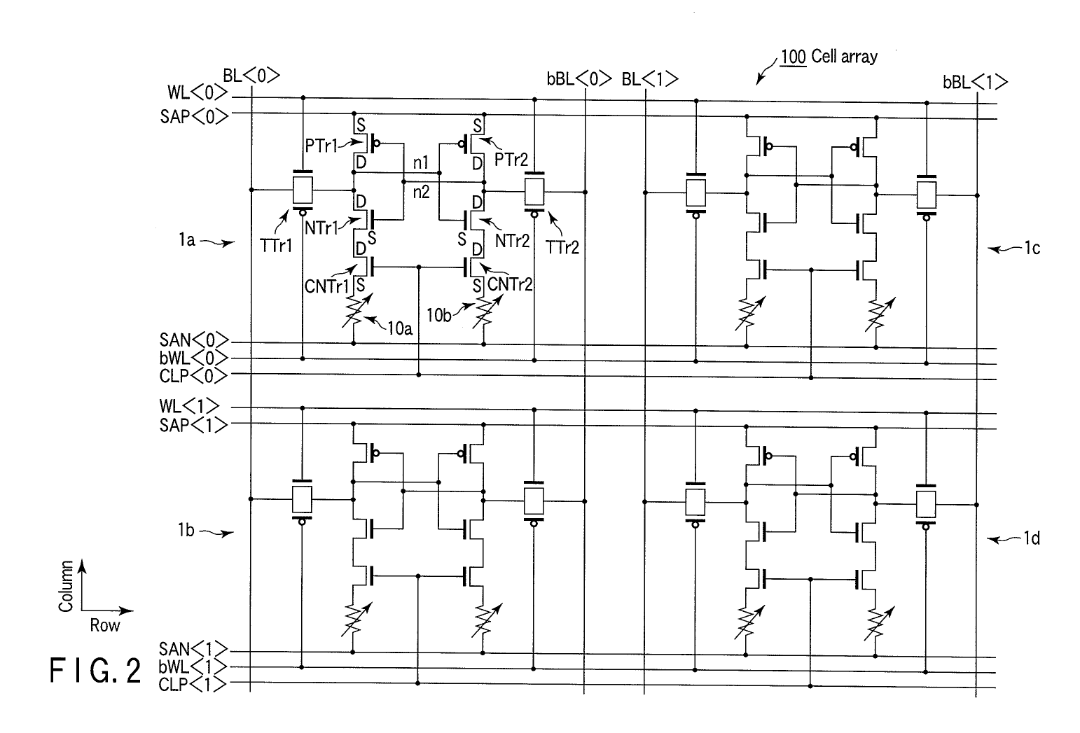

A cell array in which ROM cells according to the first embodiment of the present invention are arranged in an array form will be described below. It should be noted that in FIG. 2, the direction in which bit lines BL and bBL extend is defined as the column direction, and direction in which the word lines WL and bWL extend is defined as the row direction.

As shown in FIG. 2, a plurality of ROM cells 1a, 1b, 1c, and 1d are arranged in an array form, thereby constituting a cell array 100. Here, the ROM cells 1a and 1b arranged in the same column direction share bit lines BL<0> and bBL<0> with each other, and ROM cells 1c and 1d arranged in the same column direction share bit lines BL<1> and bBL<1> with each other. Further, the ROM cells 1a and 1c arranged in the same row direction share the word lines WL<0> and bWL<0> with each other, and ROM cells 1b and 1d arranged in the same row direction share the word lines WL<1> and bWL<1> with each other.

As shown in FIG. 3, a column decoder 101, row decoder 102, and peripheral circuit 103 are arranged on the periphery of the cell array 100. One column is selected from the plurality of columns by the column decoder 101, and one row is selected from the plurality of rows by the row decoder 102. As a result of this, one ROM cell 1 is selected. The peripheral circuit 103 receives an address signal, data signal, and control signal, and carries out control of an address selection, write operation, and read operation.

### [1-3] Write Operation

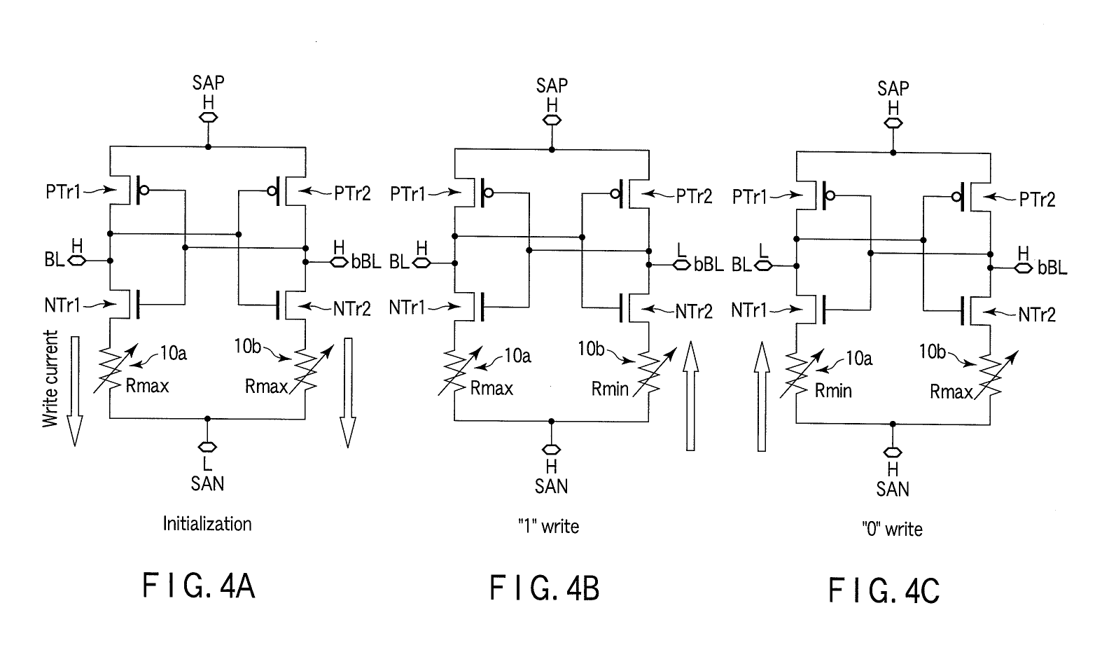

A cell write operation according to the first embodiment of the present invention will be described below with reference to FIGS. 4A to 4C, 5, and 6. It should be noted that in FIGS. 4A to 4C, voltage clamp NMOS transistors CNTr1 and CNTr2 shown in FIG. 1 do not participate in the write operation, and are hence omitted. Further, CMOS transfer gate transistors TTr1 and TTr2 shown in FIG. 1 are on at the time of the write operation, and are hence omitted. That is, the word line WL is made high (set at the H level) (for example, power source potential VDD), and word line bWL is made low (set at the L level) (for example, ground potential VSS).

First, before carrying out the write operation, initialization of the ROM cell 1 is carried out. In this case, as shown in FIGS. 4A, 5, and 6, the first common node SAP, and bit lines BL and bBL are made high, and second common node SAN is made low. In this way, a write current is applied in the direction from bit line BL to the second common node SAN, and resistance change element 10a is set in the high-resistance state Rmax. Further, a write current is applied in the direction from bit line bBL to the second common node SAN, and resistance change element 10b is set in the high-resistance state Rmax. Accordingly, both the pair of resistance change elements 10a and 10b is set in the high-resistance state by the initialization.

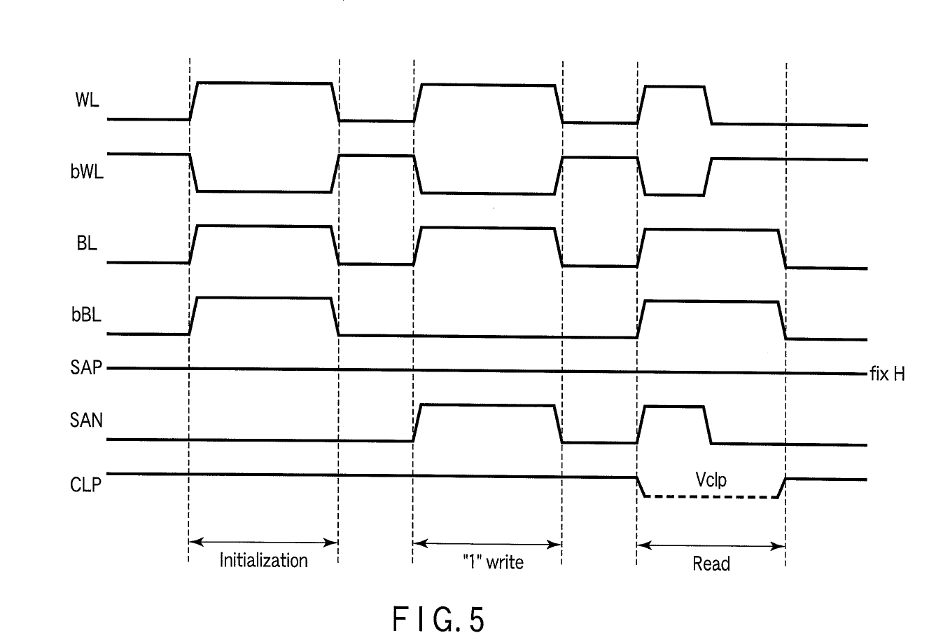

Then, binary 1 write is carried out in the following manner after the initialization is carried out. That is, as shown in FIGS. 4B, and 5, the first common node SAP, second common node SAN, and bit line BL are made high, and bit line bBL is made low. In this way, a write current is applied in the direction from the second common node SAN to bit line bBL, and resistance change element 10b is set in the low-resistance state Rmin. At this time, no write current is applied to resistance change element 10a, and hence resistance change element 10a remains in the high-resistance state.

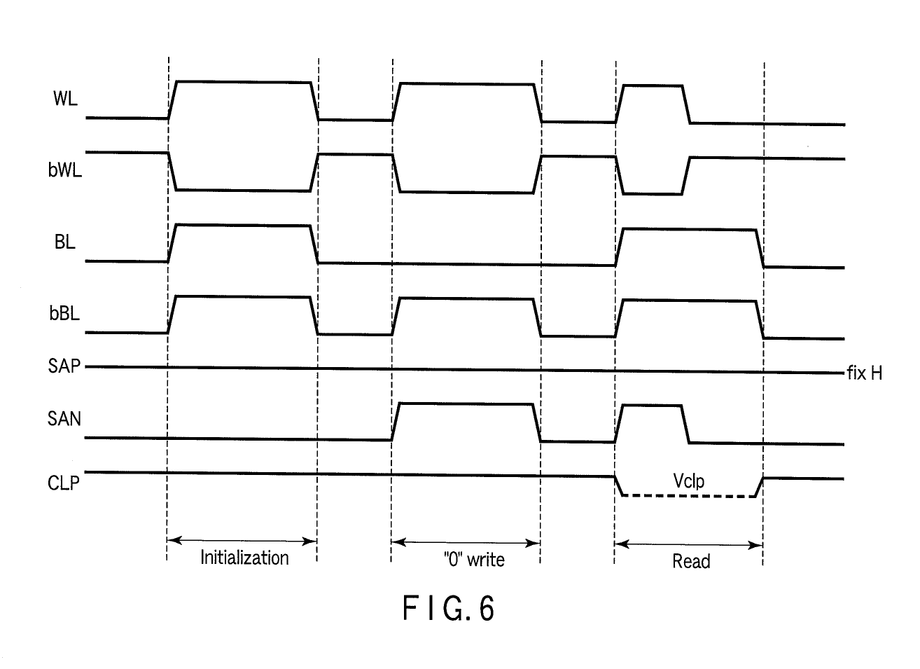

On the other hand, binary 0 write is carried out in the following manner after the initialization. That is, as shown in FIGS. 4C and 6, the first common node SAP, second common node SAN, and bit line bBL are made high, and bit line BL is made low. In this way, the write current is applied in the direction from the second common node SAN to bit line BL, and resistance change element 10a is set in the low-resistance state Rmin. At this time, no write current is applied to resistance change element 10b, and hence resistance change element 10b remains in the high-resistance state Rmax.

It should be noted that in the write operation, both the pair of resistance change elements 10a and 10b may be set in the low-resistance state Rmin at the time of initialization. In this case, at the time of binary 1 write, resistance change element 10a is set in the low-resistance state Rmin, and resistance change element 10b is set in the high-resistance state Rmax. Further, at the time of binary 0 write, resistance change element 10a is set in the high-resistance state Rmax, and resistance change element 10b is set in the low-resistance state Rmin. The connection directions of resistance change elements 10a and 10b may be changed so that the setting can be carried out in the above manner.

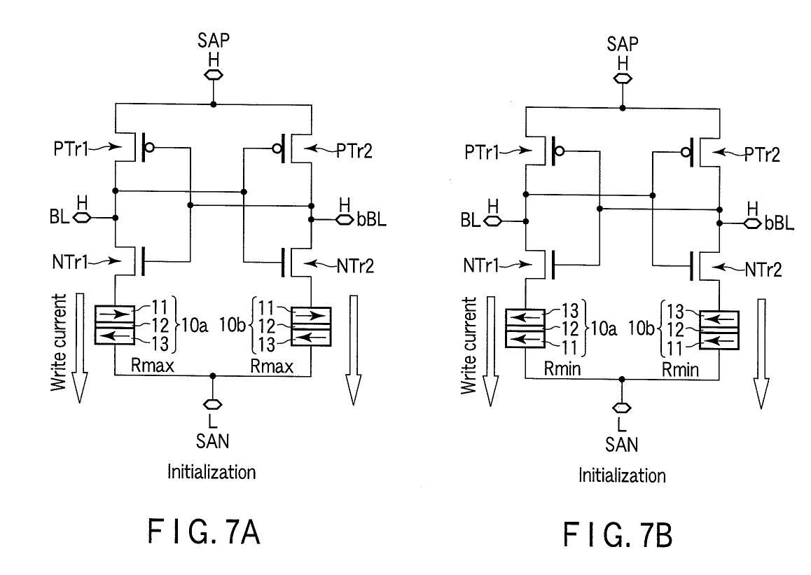

For example, as shown in FIGS. 7A and 7B, in the case of the spin injection MRAM, the connection of the magnetoresistive effect elements i.e., resistance change elements 10a and 10b in the case where the resistance change elements are set in the high-resistance state Rmax at the time of initialization and the connection in the case where the resistance change elements are set in the low-resistance state Rmin are opposite to each other.

Here, each of resistance change elements 10a and 10b includes at least a fixed layer 11, recording layer (free layer) 13, and intermediate layer 12 provided between the fixed layer 11 and recording layer 13.

More specifically, as shown in FIG. 7A, when the resistance change elements are set in the high-resistance state Rmax at the time of initialization, the fixed layers 11 is respectively connected to the NMOS transistor NTr1 side, NMOS transistor NTr2 side, and recording layers 13 is connected to the second common node SAN side. Further, the magnetization direction of the recording layer 13 set in the direction parallel to the magnetization direction of the fixed layer 11 is reversed and set in the direction antiparallel to the magnetization direction of the fixed layer 11. In this case, a write current is made to flow from the fixed layer 11 to the recording layer 13. That is, an electron stream is made to flow from the recording layer 13 to the fixed layer 11. The electron stream is transmitted through the recording layer 13. Thereafter, many of electrons having a spin antiparallel to the magnetization direction of the fixed layer 11 in the electron stream are reflected by the fixed layer 11, and are returned to the recording layer 13. Further, these electrons are made to flow into the recording layer 13 again. That is, the electrons having a spin antiparallel to the magnetization direction of the fixed layer 11 make the main contribution to the torque acting in the magnetization of the recording layer 13. It should be noted that part of the electrons transmitted through the recording layer 13, and having a spin antiparallel to the magnetization direction of the fixed layer 11 are transmitted through the fixed layer 11 although their number is small.

On the other hand, as shown in FIG. 7B, when the resistance change elements are set in the low-resistance state Rmin at the time of initialization, the fixed layer 11 is connected to the second common node SAN side, and recording layer 13 is connected to the NMOS transistor NTr1 side or NMOS transistor NTr2 side. Further, the magnetization of the recording layer 13 set in the direction antiparallel to the magnetization direction of the fixed layer 11 is reversed and set in the direction parallel to the magnetization direction of the fixed layer 11. In this case, a write current is made to flow from the recording layer 13 to the fixed layer 11. That is, an electron stream is made to flow from the fixed layer 11 to the recording layer 13. In general, a large part of an electron stream passing through a certain magnetic substance has a spin parallel to the magnetization direction of the magnetic substance. Accordingly, a large part of the electron stream that has passed through the fixed layer 11 has a spin parallel to the magnetization direction of the fixed layer 11. This part of the electron stream makes the main contribution to the torque acting in the magnetization of the recording layer 13. It should be noted that the remaining part of the electron stream has a spin antiparallel to the magnetization direction of the fixed layer 11.

### [1-4] Read Operation

A cell read operation according to the first embodiment of the present invention will be described below with reference to FIGS. 5 and 6. In the read operation, by utilizing a difference in resistance between the pair of resistance change elements 10a and 10b, the output of the latch circuit is determined.

First, before starting the read operation, the word line WL is made high, word line bWL is made low, thereby turning CMOS transfer gate transistors TTr1 and TTr2 on. Furthermore, bit line BL, bit line bBL, first common node SAP, and second common node SAN are made high, and a control voltage Vclp is applied as a clamp control voltage CLP.

Then, after starting the read operation, the word line WL is made low, and word line bWL is made high, thereby turning CMOS transfer gate transistors TTr1 and TTr2 off. Furthermore, the second common node SAN is made low. In this manner, a read current is applied in the direction from the first output node n1 to resistance change element 10a, and a read current is applied in the direction from the second output node n2 to resistance change element 10b. At this time, voltages to be applied to resistance change elements 10a and 10b are controlled in such a manner that these voltages take substantially the values of (control voltage Vclp−threshold voltage of NMOS transistor NTr1), and (control voltage Vclp−threshold voltage of NMOS transistor NTr2), respectively. Here, the control voltage Vclp is adjusted to take such a sufficiently small value that the read current does not cause write to resistance change elements 10a and 10b, and is adjusted to take a voltage value between the high and low.

Thereafter, when the cell stores binary 1, the output of the latch circuit is determined in such a manner that bit line BL goes high, and bit line bBL goes low. On the other hand, when the cell stores binary 0, the output of the latch circuit is determined in such a manner that bit line BL goes low, and bit line bBL goes high. After the output of the latch circuit is determined, supply of the read current is automatically stopped.

It should be noted that the read operation may be simultaneously carried out for a plurality of cells. Further, the output of the latch circuit of a cell selected by an address signal after the read operation is output as a data signal.

### [1-5] Advantage

According to the first embodiment described above, in the ROM cell 1, a pair of resistance change elements 10a and 10b to which data can be written by directly applying a current thereto is used. Further, initialization is carried out before the write operation is started, then after setting resistance change elements 10a and 10b in the same state, one of resistance change elements 10a and 10b is set in the low-resistance state, and the other of resistance change elements 10a and 10b is set in the high-resistance state, whereby binary 1 or binary 0 write is carried out. As described above, according to this embodiment, it is possible to realize a ROM cell 1 in which resistance change elements 10a and 10b configured in such a manner that data can be written by directly applying a current are used.

### Second Embodiment

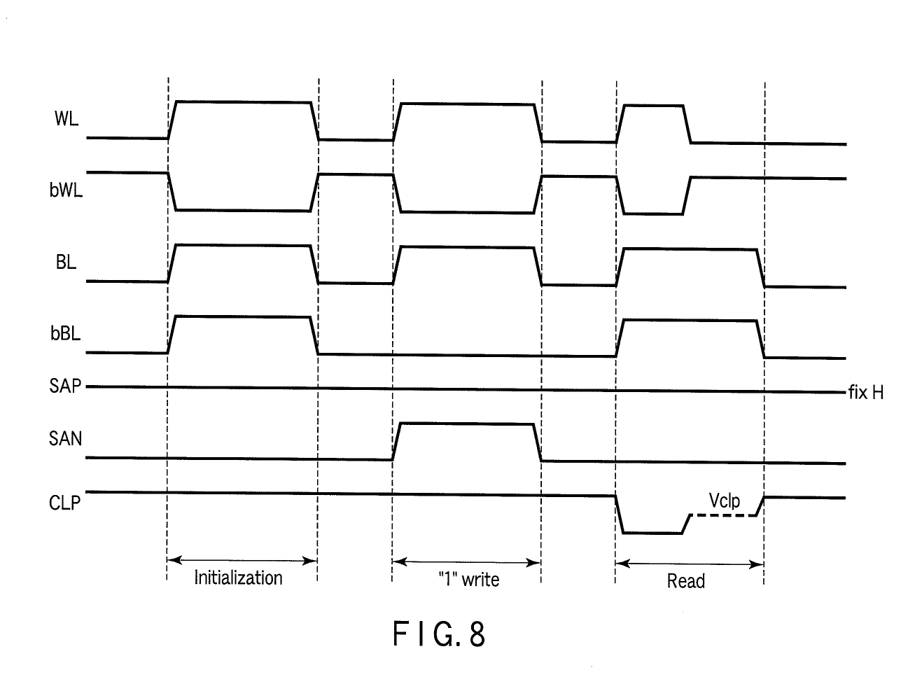

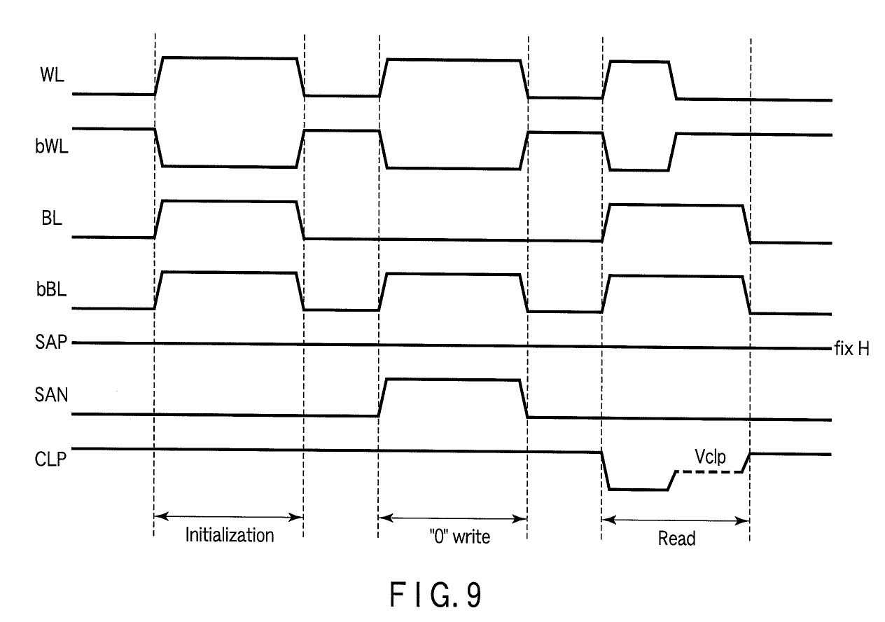

A second embodiment is identical with the first embodiment in the procedure of the write operation. However, the second embodiment differs from the first embodiment in the procedure of the read operation. That is, in the first embodiment, the read operation is controlled by the second common node SAN. Conversely, in the second embodiment, the read operation is controlled by voltage clamp NMOS transistors CNTr1 and CNTr2. The read operation in the second embodiment will be described below with reference to FIGS. 8 and 9.

First, before starting the read operation, a word line WL is made high, word line bWL is made low, thereby turning CMOS transfer gate transistors TTr1 and TTr2 on. Furthermore, a bit line BL, bit line bBL, and first common node SAP are made high, and second common node SAN and clamp control voltage CLP are made low.

Then, after the read operation is started, the word line WL is made low, word line bBL is made high, thereby turning CMOS transfer gate transistors TTr1 and TTr2 off. Furthermore, the clamp control voltage CLP is changed to a control voltage Vclp. In this manner, a read current is applied in the direction from a first output node n1 to a resistance change element 10a, and a read current is applied in the direction from a second output node n2 to a resistance change element 10b. At this time, voltages to be applied to resistance change elements 10a and 10b are controlled in such a manner that these voltages take substantially the values of (control voltage Vclp−threshold voltage of NMOS transistor NTr1), and (control voltage Vclp−threshold voltage of NMOS transistor NTr2), respectively. Here, the control voltage Vclp is adjusted to take such a sufficiently small value that the read current does not cause write to resistance change elements 10a and 10b, and is adjusted to take a voltage value between high and low.

Thereafter, when the cell stores binary 1, the output of the latch circuit is determined in such a manner that bit line BL goes high, and bit line bBL goes low. On the other hand, when the cell stores binary 0, the output of the latch circuit is determined in such a manner that bit line BL goes low, and bit line bBL goes high. After the output of the latch circuit is determined, supply of the read current is automatically stopped.

### Third Embodiment

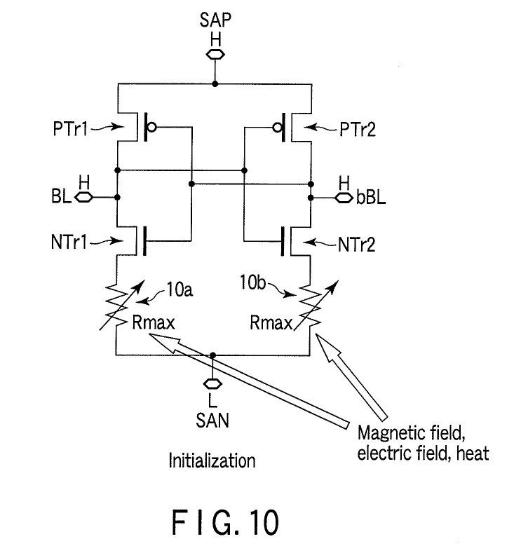

A third embodiment differs from the first embodiment in the method of initialization. That is, as shown in FIG. 10, in place of applying a write current to each of resistance change elements 10a and 10b, one of a magnetic field, electric field, and heat is applied to the ROM cell 1 from outside. As a result of this, a plurality of resistance change elements 10a and 10b can be simultaneously set in the same high-resistance state Rmax or low-resistance state Rmin.

It should be noted that examples of resistance change element 10a or 10b in the ROM cell 1 of each of the above embodiments include a magnetoresistive effect element in a spin injection MRAM, transition metal oxide element in an ReRAM, phase change element in a PRAM, and the like. Further, the ROM cell 1 in each of the above embodiments is not limited to a ROM, and the embodiments can be applied to various semiconductor memory devices such as an MRAM, ReRAM, PRAM, and the like.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising a memory circuit, wherein
the memory circuit comprises:
a first transistor of a first conductivity type, comprising a drain connected to a first output node, a gate connected to a second output node, and a source connected to a first common node;
a second transistor of the first conductivity type, comprising a drain connected to the second output node, a gate connected to the first output node, and a source connected to the first common node;
a third transistor of a second conductivity type, comprising a drain connected to the first output node, a gate connected to the second output node, and a source connected to a first connection node;
a fourth transistor of the second conductivity type, comprising a drain connected to the second output node, a gate connected to the first output node, and a source connected to a second connection node;
a first resistance change element, comprising a first end connected to the first connection node, and a second end connected to a second common node; and
a second resistance change element, comprising a first end connected to the second connection node, and a second end connected to the second common node,
voltages of the first common node, the second common node, and the first output node are set substantially at a first reference voltage, and a voltage of the second output node is set substantially at a second reference voltage different from the first reference voltage, whereby a current is directly applied to the second resistance change element, when the memory circuit stores therein first data, and
voltages of the first common node, the second common node, and the second output node are set substantially at the first reference voltage, and a voltage of the first output node is set substantially at the second reference voltage, whereby a current is directly applied to the first resistance change element, when the memory circuit stores therein second data.

2. The device of claim 1, wherein
initialization of the memory circuit is carried out before storing the first data or the second data, and
a voltage of the second common node is set substantially at the second reference voltage, and voltages of the first common node, the first output node, and the second output node are set substantially at the first reference voltage in the initialization, whereby resistance states of the first resistance change element and the second resistance change element are substantially identical with each other by applying a current to the first resistance change element and the second resistance change element.

3. The device of claim 1, wherein
voltages of the first common node, the second common node, the first output node, and the second output node are set substantially at the first reference voltage before starting a read operation, and
a voltage of the second common node is changed to the second reference voltage after starting the read operation.

4. The device of claim 3, wherein
the memory circuit further comprises:
a fifth transistor of the second conductivity type, comprising a drain connected to the first connection node, a gate configured to receive a control voltage, and a source connected to the first end of the first resistance change element; and
a sixth transistor of the second conductivity type, comprising a drain connected to the second connection node, a gate configured to receive the control voltage, and a source connected to the first end of the second resistance change element, and
a current used to read either the first data or the second data in the memory circuit is controlled by the control voltage.

5. The device of claim 4, wherein
voltages of the first common node, the second common node, the first output node, and the second output node are set substantially at the first reference voltage, and the control voltage is set at a third reference voltage before starting the read operation, and
a voltage of the second common node is changed substantially to the second reference voltage after starting the read operation.

6. The device of claim 5, wherein
the third reference voltage is between the first reference voltage and the second reference voltage.

7. The device of claim 4, wherein
voltages of the first common node, the first output node, and the second output node are set substantially at the first reference voltage, and a voltage of the second common node and the control voltage are set substantially at the second reference voltage before starting the read operation, and
the control voltage is changed substantially to a third reference voltage after starting the read operation.

8. The device of claim 7, wherein
the third reference voltage is between the first reference voltage and the second reference voltage.

9. The device of claim 1, wherein
a plurality of the memory circuits are aligned in an array form in a first interconnect direction and a second interconnect direction perpendicular to the first interconnect direction,
each of a plurality of the memory circuits aligned in the first interconnect direction are connected to each other with sharing the first interconnect, and
each of a plurality of memory circuits aligned in the second interconnect direction are connected to each other with sharing the second interconnect.

10. The device of claim 1, wherein
each of the first and the second resistance change elements is one of a magnetoresistive effect element, a transition metal oxide element and a phase change element.

11. The device of claim 10, wherein
each of the resistance change elements comprises a fixed layer comprising the magnetization direction fixed in one direction, and a recording layer comprising the magnetization direction reversed by spin injection, when the first and the second resistance change elements are magnetoresistive effect elements,
the fixed layer is connected to the first or the second connection node and the recording layer is connected to the second common node, or the fixed layer is connected to the second common node and the recording layer is connected to the first or the second connection node.

12. The device of claim 1, wherein
the first reference voltage is a power source potential, and the second reference voltage is the ground potential.

13. The device of claim 1, wherein
initialization of the memory circuit is carried out before storing the first data or the second data, and
one of a magnetic field, electric field, and heat is applied to the memory circuit in the initialization, whereby the resistance states of the first resistance change element and the second resistance change element are substantially identical with each other.

14. A semiconductor memory device comprising a memory circuit, wherein
the memory circuit comprises:
a latch circuit connected to a first common node, a first output node, a second output node, a first connection node, and a second connection node;
a first resistance change element comprising a first end connected to the first connection node and a second end connected to a second common node; and
a second resistance change element comprising a first end connected to the second connection node, and a second end connected to the second common node,
voltages of the first common node, the second common node, and the first output node are set substantially at a first reference voltage, and a voltage of the second output node is set substantially at a second reference voltage different from the first reference voltage, whereby a current is directly applied to the second resistance change element, when the memory circuit stores therein first data, and
the second common node, and the second output node are set substantially at the first reference voltage, and a voltage of the first output node is set substantially at the second reference voltage, whereby a current is directly applied to the first resistance change element when the memory circuit stores therein second data, voltages of the first common node.

15. The device of claim 14, wherein
the latch circuit comprises:
a first transistor of a first conductivity type, comprising a drain connected to the first output node, a gate connected to the second output node, and a source connected to the first common node;
a second transistor of the first conductivity type, comprising a drain connected to the second output node, a gate connected to the first output node, and a source connected to the first common node;
a third transistor of a second conductivity type, comprising a drain connected to the first output node, a gate connected to the second output node, and a source connected to the first connection node; and
a fourth transistor of the second conductivity type, comprising a drain connected to the second output node, a gate connected to the first output node, and a source connected to the second connection node.

16. The device of claim 14, wherein
initialization of the memory circuit is carried out before storing the first data or the second data, and
a voltage of the second common node is set substantially at the second reference voltage, and voltages of the first common node, the first output node, and the second output node are set substantially at the first reference voltage in the initialization, whereby the resistance states of the first resistance change element and the second resistance change element are substantially identical with each other by applying a current to each of the first resistance change element and the second resistance change element.

17. The device of claim 14, wherein
voltages of the first common node, the second common node, first output node, and the second output node are set substantially at the first reference voltage before starting a read operation, and
a voltage of the second common node is changed substantially to the second reference voltage after starting the read operation.

18. The device of claim 17, wherein
the memory circuit further comprises:
a fifth transistor of the second conductivity type, comprising a drain connected to the first connection node, a gate configured to receive a control voltage, and a source connected to the first end of the first resistance change element; and
a sixth transistor of the second conductivity type, comprising a drain connected to the second connection node, a gate configured to receive the control voltage, and a source connected to the first end of the second resistance change element, and
a current used to read either the first data or the second data in the memory circuit is controlled by the control voltage.

19. The device of claim 18, wherein
voltages of the first common node, the second common node, the first output node, and the second output node are set substantially at the first reference voltage, and the control voltage is set substantially at a third reference voltage between the first reference voltage and second reference voltage before starting the read operation, and
a voltage of the second common node is changed substantially to the second reference voltage after starting the read operation.

20. The device of claim 18, wherein
voltages of the first common node, the first output node, and the second output node are set substantially at the first reference voltage, and a voltage of the second common node and the control voltage are set substantially at the second reference voltage before starting the read operation, and
the control voltage is changed to a third reference voltage between the first reference voltage and second reference voltage after starting the read operation.
